(19) United States
(12) Patent Application Publication
(10) Pub. No.: US 2006/0014085 A1
(43) Pub. Date: Jan. 19, 2006

(54) Anisotropic light diffusion adhesive layer, anisotropic light diffusion adhesive laminate, and illuminating device having anisotropic light diffusion adhesive laminate

(75) Inventors: Toshihiro Nakajima, Shizuoka-ken (JP); Kensaku Higashi, Fujieda (JP)

Correspondence Address: WOOD, HERRON & EVANS, LLP, 2700 CAREW TOWER, 441 VINE STREET, CINCINNATI, OH, 45202, US

(73) Assignee: Tomoegawa Paper Co., Ltd., Chuo-ku, Tokyo (JP)

(21) Appl. No.: 10/534,581

(22) PCT Filed: Nov. 13, 2003
(86) PCT No.: PCT/JP03/14478

§ 371 Date: May 11, 2005

(30) Foreign Application Priority Data
Nov. 14, 2002 (JP) 2002-330476
Feb. 19, 2003 (JP) 2003-41015
Feb. 24, 2003 (JP) 2003-45883

(51) Int. Cl. G03F 1/00

(52) U.S. Cl. 430/7

(57) ABSTRACT

An anisotropic light diffusion adhesive layer includes an adhesive material, and an acicular filler whose refractive index is different from that of the adhesive material, wherein the acicular filler is dispersed as oriented substantially in the same direction. It is desirable for the acicular filler to be colorless or white colored. An anisotropic light diffusion adhesive laminated assembly may also be manufactured by adhering together several such anisotropic light diffusion adhesive layers. This anisotropic light diffusion adhesive layer and anisotropic light diffusion adhesive laminated assembly may suitably be employed as an illumination device such as a backlight for a liquid crystal display device or the like.

### TECHNICAL FIELD

The present invention relates to an anisotropic light diffusion adhesive layer, an anisotropic light diffusion adhesive laminated assembly, a multi layer sheet, an optical laminated assembly, and an illumination device, which are suitable for use in an illumination device such as a backlight of a liquid crystal display device or the like.

### BACKGROUND ART

Various types of optical element are used in a liquid crystal display device; for example, a light reflection element, a light diffusion element, a prism element, a light polarization element, and the like are widely used in a backlight.

Among these optical elements, as a light diffusion element, there are known one which includes, within a film base material, a filler which has a refractive index which is different from that of the base material, and one which is formed with a large number of minute convexities and concavities in a resin layer of the film surface by a replication method, and one in which a paint which includes a filler is coated upon a transparent film, and the like. With such a prior art light diffusion element, in general, when a thin straight light beam is directed to be perpendicularly incident upon it, the transmitted light is diffused isotropically, so that, when this transmitted light is projected upon a sheet of white paper or the like, the optical image appears in the form of a circle.

In recent years an anisotropic light diffusion element has been proposed as a light diffusion element, with which the transmitted light is not diffused isotropically, but rather is diffused as biased in a particular direction. If light which has been transmitted through such an anisotropic light diffusion element is projected, the optical image which is obtained is not circular, but rather appears in the form of a straight line or of an ellipse.

As such an anisotropic light diffusion element, for example, the following proposals have been presented.

In Japanese Unexamined Patent Application, First Publications Nos. S59-176734 and H08-327805, a projection screen is disclosed in which fibrous particles or acicular particles are dispersed within a base material, and are oriented in a single direction.

In Japanese Unexamined Patent Application, First Publication No. 2001-249205, there is disclosed a light diffusion sheet in which an anisotropic diffusion layer, in which a fibrous light diffusion material, which is dispersed substantially in parallel in a binder, is provided above a base material layer.

In Japanese Unexamined Patent Application, First Publications Nos. H02-199444, H04-314522, and H09-311205, there is disclosed a projection screen or a light diffusing sheet, in which, in a transparent matrix, there is dispersed a rod shaped resin whose refractive index is different from that of the transparent matrix, and which is oriented in a uniform direction; and it is described that this may be manufactured by processing a resin composite in which sea islands are formed which have a different refractive index by stretching it out, thus deforming the minute resin particles which correspond to islands into rod shapes and orienting them.

In Japanese Unexamined Patent Application, First Publication No. 2002-98810, there is disclosed an anisotropic diffusion sheet in which, instead of fibrous particles or minute resin particles, rod shaped air bubbles are oriented in parallel to the surface of a sheet and moreover in a uniform direction.

In Japanese Unexamined Patent Application, First Publication No. H10-119125, there is disclosed a method for manufacturing a transmitted light scattering controlled film by controlling the conditions in which a thermoplastic macromolecular resin film is stretched along a single axis, so as to generate grooves which extend in a direction which is perpendicular to the direction in which the film is stretched.

Apart from the above, a large number of examples have also been proposed for accurately controlling the diffusion direction of light or of a projected image by surface relief hologram techniques.

In many cases, anisotropic light diffusion elements proposed in the prior art are manufactured by a process of stretching a resin sheet. Due to this, manufacturing techniques which involve large scale equipment and high production rate are required, and there are difficulties in responding to demands for small scale production of devices of varying degree of anisotropy for transmitted light or thickness.

In this connection, although, with optical elements for liquid crystal display devices, there are some which are assembled to the liquid crystal display device by being adhered with an adhesive material, in applications according to the prior art, a transparent acryl type adhesive material is widely used. Moreover, in Published Japanese Translation No. H11-508622 of the PCT International Publication and Japanese Unexamined Patent Application, First Publications No. H11-223712, there is disclosed a light diffusion adhesive layer which exhibits a light diffusion function which is made by dispersing, within the adhesive layer which consists of this acryl type adhesive material, minute particles which have a different refractive index from this adhesive material.

The manufacture of this light diffusion adhesive layer is comparatively easy, and it is also easy to adjust its thickness. However, the light diffusion function of a light diffusion adhesive layer as proposed in prior art is one which is isotropic, and one which exhibits anisotropy has not been reported.

### DISCLOSURE OF INVENTION

The present invention was made in light of the above described circumstances, and an object thereof is to provide an anisotropic light diffusion adhesive layer which is endowed with both an anisotropic light diffusion function and an adhesive function, and a laminated assembly and an illumination device which use this layer, and, moreover, an anisotropic light diffusion adhesive laminated assembly which is endowed with both an anisotropic light diffusion function and an adhesive function, and a multi layer sheet, an optical laminated assembly, and an illumination device which use this layer.

In order to solve the above described problems, the present invention provides an anisotropic light diffusion adhesive layer containing an adhesive material, and an acicular filler whose refractive index is different from that of the adhesive material, wherein the acicular filler is dispersed as oriented substantially in the same direction.

The present invention further provides a laminated assembly which includes the above described anisotropic light diffusion adhesive layer according to the present invention.

The optical laminated assembly of the present invention may be suitably utilized in various types of optical device, such as a liquid crystal display device or the backlight for a liquid crystal display device or the like.

The present invention further provides an illumination device which includes the above described anisotropic light diffusion adhesive layer according to the present invention. In more concrete terms, it is desirable for this illumination device to include, as indispensable structural members, a light source, a light guiding plate, and a light reflection element; and further to include, as an optional structural member, a light diffusion element, a prism element, a light polarization element, a phase difference element, or a viewing angle magnification element; and for the anisotropic light diffusion adhesive layer according to the present invention to be sandwiched between a pair of optical elements selected from the light guiding plate, the light reflection element, the light diffusion element, the prism element, the light polarization element, the phase difference element, and the viewing angle magnification element.

The present invention further provides an adhesive laminated assembly including two or more adhesive layers which comprise an adhesive material, wherein, along with at least one of the adhesive layers including acicular filler whose refractive index is different from that of the adhesive material, the acicular filler is dispersed as oriented substantially in the same direction.

The present invention further provides a multi layer sheet which includes the above anisotropic light diffusion adhesive laminated assembly, and a transparent base material which has two surfaces, with the anisotropic light diffusion adhesive laminated assembly being provided upon at least one of the surfaces of the transparent base material.

The present invention further provides an optical laminated assembly which includes the above described anisotropic light diffusion adhesive laminated assembly and a separator, and which further includes an optical element selected from a light reflection element, a light diffusion element, a prism element, a light polarization element, a phase difference element, and a viewing angle magnification element; and in which the anisotropic light diffusion adhesive laminated assembly and the separator are laminated in order upon the optical element. This optical laminated assembly may be suitably utilized in various types of optical device, such as a liquid crystal display device or the backlight for a liquid crystal display device or the like.

The present invention further provides an illumination device which includes the above described anisotropic light diffusion adhesive laminated assembly according to the present invention. In more concrete terms, it is desirable for this illumination device to include, as indispensable structural members, a light source, a light guiding plate, and a light reflection element; and further to include, as an optional structural member, a light diffusion element, a prism element, a light polarization element, a phase difference element, or a viewing angle magnification element; and for the anisotropic light diffusion adhesive assembly according to the present invention to be sandwiched between a pair of optical elements selected from the light guiding plate, the light reflection element, the light diffusion element, the prism element, the light polarization element, the phase difference element, and the viewing angle magnification element.

### BRIEF DESCRIPTION OF THE DRAWINGS

FIG. 1 is a sectional view showing an example of an anisotropic light diffusion adhesive laminated assembly according to the present invention.

FIGS. 2A and 2B are figures for explanation of the anisotropic light diffusion mechanism of an anisotropic light diffusion adhesive layer according to the present invention, and are figures showing when the anisotropic light diffusion adhesive layer contains an acicular filler.

FIGS. 3A and 3B are figures for explanation of the anisotropic light diffusion mechanism of an anisotropic light diffusion adhesive layer according to the present invention, and are figures showing when the anisotropic light diffusion adhesive layer contains an acicular filler and a globular filler.

FIGS. 4A and 4B are figures for explanation of the light diffusion situation by an anisotropic light diffusion adhesive laminated assembly which has been made by laminating together two laminated assemblies so that the directions of orientation of their acicular fillers are mutually orthogonal.

FIGS. 5A and 5B are figures for explanation of the reason why no anisotropic light diffusion function is manifested by a light diffusion adhesive layer in which, instead of an acicular filler, a globular filler is used.

### BEST MODE FOR CARRYING OUT THE INVENTION

In the following, the present invention will be described in detail.

(An Anisotropic Light Diffusion Adhesive Layer)

The anisotropic light diffusion adhesive layer of the present invention, along with including an adhesive material and an acicular filler which has a different refractive index from the adhesive material, is also characterized in that the acicular filler is dispersed so as to be oriented in roughly the same direction.

However, with the anisotropic light diffusion adhesive layer of the present invention, it is sufficient for the acicular filler to be oriented to an extent at which it manifests its anisotropic diffusion function, which is the objective of the present invention; and it is not absolutely necessary for all of this acicular filler to be accurately oriented.

(An Anisotropic Light Diffusion Adhesive Laminated Assembly)

The anisotropic light diffusion adhesive laminated assembly of the present invention is an adhesive laminated assembly which includes two or more adhesive layers which include adhesive material, and of which at least one adhesive layer, along with including an adhesive material and an acicular filler which has a different refractive index from the adhesive material, is also characterized in that the acicular filler is dispersed so as to be oriented in roughly the same direction.

However, with the anisotropic light diffusion adhesive laminated assembly of the present invention, it is sufficient for the acicular filler to be oriented to an extent at which it manifests its anisotropic diffusion function, which is the objective of the present invention; and it is not absolutely necessary for all of this acicular filler to be accurately oriented.

With the present invention, the element which manifests anisotropic light diffusion is the adhesive layer (the anisotropic light diffusion adhesive layer) which includes the acicular filler which is oriented, even though it is within the adhesive laminated assembly.

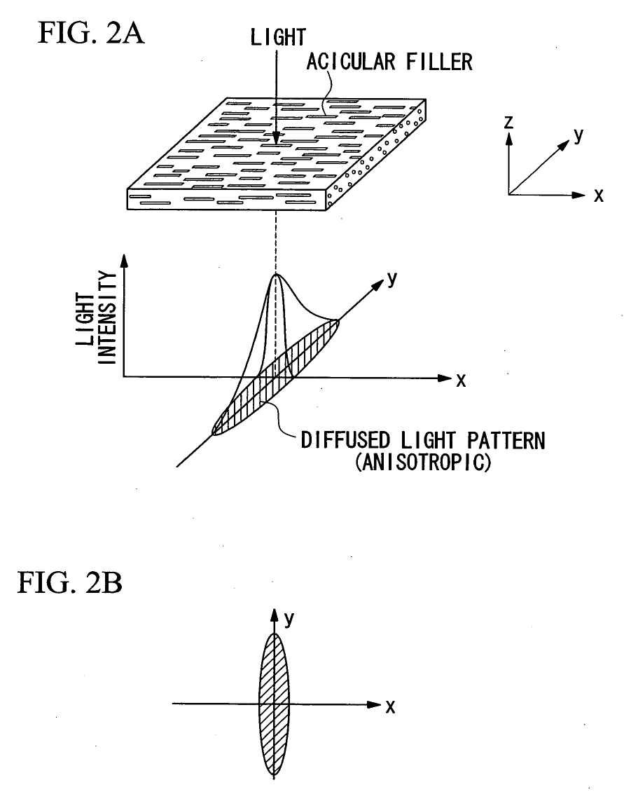

The mechanism of anisotropic light diffusion by the anisotropic light diffusion adhesive layer of the present invention will be explained in a simple manner based upon FIGS. 2A and 2B. FIG. 2A is a figure showing in schematic form the anisotropic light diffusion adhesive layer of the present invention, and the state of diffusion of transmitted light when a thin straight light beam is perpendicularly incident upon it; and FIG. 2B is a figure showing in schematic form the projected image of light transmitted through the anisotropic light diffusion adhesive layer of the present invention. It should be understood that, in FIGS. 2A and 2B, for the sake of convenience, the lengthwise direction of the acicular filler is taken as the “x” axis direction, the surface of the anisotropic light diffusion adhesive layer is taken as the “xy” plane, and the thickness direction of the anisotropic light diffusion adhesive layer is taken as the “z” axis.

As shown in FIGS. 2A and 2B, when a straight light beam is perpendicularly incident upon the anisotropic light diffusion adhesive layer of the present invention, this incident light beam is refracted at the surfaces of the acicular filler, which has a different refractive index from the adhesive material. As a result, the amount of diffused light in the plane which is orthogonal to the lengthwise axis direction of the acicular filler and in its vicinity comes to be increased, so that the diffused light exhibits anisotropy. In other words, the projected image of the transmitted light beam comes to be an elliptical shape which is stretched out in the direction which is orthogonal to the lengthwise axis direction of the acicular filler.

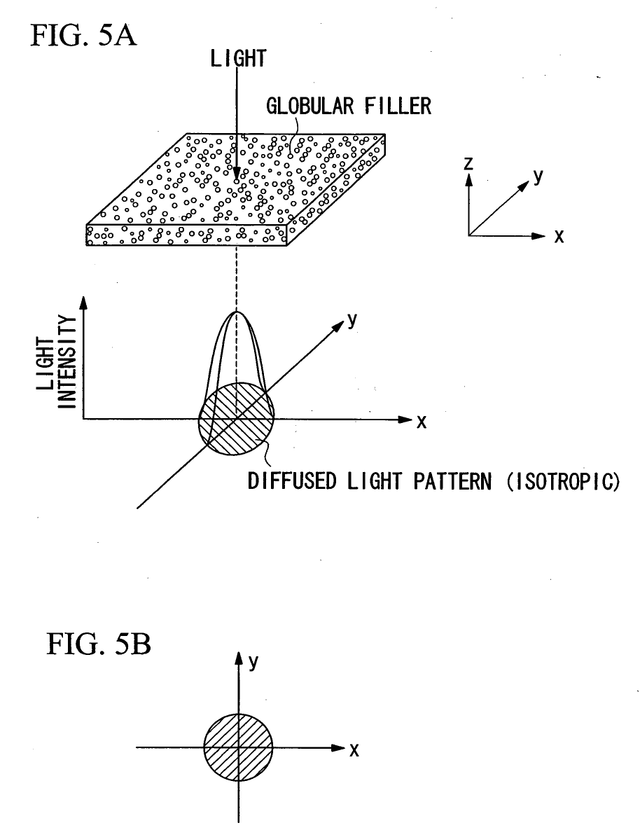

It should be understood that, with a light diffusion adhesive layer in which, instead of an acicular filler, there is utilized a globular filler or a filler of indeterminate form, as shown in FIGS. 5A and 5B, the beam of incident light comes to be isotropically diffused by the surfaces of the globular filler, and does not exhibit anisotropy. In other words, the projected image of the transmitted light beam comes to be circular.

With the anisotropic diffusion adhesive laminated assembly of the present invention, it is possible to include, not only the adhesive layer described above which exhibits anisotropic light diffusion, but also an adhesive layer which has other optical properties which are different from those of this adhesive layer. It is possible to cause it to manifest various types of optical properties.

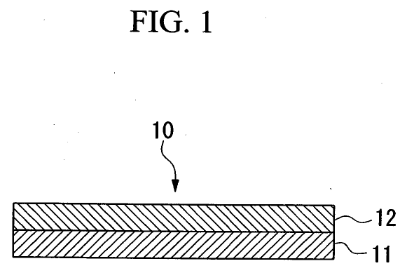

For example, as an anisotropic diffusion adhesive laminated assembly 10 as shown in FIG. 1 which includes an adhesive layer 11 which includes an oriented acicular filler, and an adhesive layer which has other optical properties which are different from those of this adhesive layer 111, there may be cited the following possibilities:
(1) One which is a lamination of an adhesive layer (A) which includes an acicular filler which is oriented, and an adhesive layer (B) which includes an acicular filler which is oriented in a different direction from that of the acicular layer (A).
(2) One which is a lamination of an adhesive layer (A) which includes an acicular filler which is oriented, and an adhesive layer (C) which includes a non-acicular filler.
(3) One which is a lamination of an adhesive layer (A) which includes an acicular filler which is oriented, and an adhesive layer (D) which includes an acicular filler which is not oriented.
(4) One which is a lamination of an adhesive layer (A) which includes an acicular filler which is oriented, and a transparent adhesive layer (E) which includes neither an acicular filler nor a non-acicular filler.
(5) One which is a lamination of an adhesive layer (A) which includes an acicular filler which is oriented, and two or more selected from the above described (B) through (E). Furthermore, it is also possible further to include a non-acicular filler within the adhesive layer which includes the acicular filler which is oriented.

Yet further, there may be three or more adhesive layers. As an anisotropic light diffusion adhesive laminated assembly which has three or more adhesive layers, for example, there may be cited one which includes, in at least two of the adhesive layers, acicular fillers which are oriented in substantially the same direction, or one in which the acicular filler which is included in each of the adhesive layers is oriented in a different direction from that of the other adhesive layers. Even if there are three or more adhesive layers, it will be acceptable for at least one of the adhesive layers to include a non-acicular filler, or to include a non-oriented acicular filler.

In the following, the structure of the anisotropic light diffusion adhesive layer of the present invention will be described in detail.

(An Adhesive Material)

Although the adhesive material which is used is not particularly limited, if the anisotropic light diffusion adhesive layer of the present invention is to be used in a liquid crystal display device or in a backlight for a liquid crystal display device or the like, it is desirable for it to satisfy the required conditions that (a) its optical transparency is high, (b) it has a refractive index which is close to that of the base layer of the anisotropic light diffusion adhesive layer is formed (for example, a TAC film, which is a protective film for a polarizing plate), (c) as an adhesive material for a light polarization element and the like, its reliability is high and its merits are numerous, (d) it should be comparatively cheap, and the like. As a material which satisfies these required conditions, an acryl type adhesive material or the like may be cited.

As the main component for the acryl type adhesive material, there may be cited homopolymers of acryl monomers such as acrylic acid and its esters, methacrylic acid and its esters, acrylamide, acrylonitrile, or copolymers thereof, or copolymers or the like of at least one type of the acryl monomers and a vinyl monomer such as acetic acid vinyl, maleic anhydride, styrene or the like.

Among these, the ones which are most suitable are copolymers which consist of a main monomer which manifests an adhesive property such as ethyl acrylate, butyl acrylate, 2-ethyl hexyl acrylate, or the like, a monomer which constitutes a cohesive component such as acetic acid vinyl, acrylamide, acrylonitrile, styrene, methacrylate, or the like, and a monomer which includes a functional group such as acrylic acid, methacrylic acid, itaconic acid, maleic anhydride, hydroxyl ethyl methacrylate, hydroxyl propyl methacrylate, dimethylamino ethyl methacrylate, methylol acrylamide, glycidyl methacrylate, or the like, and which provides a cross linked base so as to enhance the adhesive force; and their glass transition point Tg is in the range of −60° C. to −15° C., while their mass average molecular weight is in the range 100,000 to 2,000,000.

In the acryl type adhesive material, apart from the above described main component, according to requirements, there may also be combined one, or two or more, cross-linking substances such as a metallic chelate substance, an isocyanate substance, or an epoxy type substance.

Furthermore it is also possible to employ, as the acryl type adhesive material, a material which consists of a combination of an oligomer which has an acryl base on a terminator or a side chain, and a photopolymerized initiator or the like in this acryl type monomer; and, after this material has been coated upon the base material, to make this coated layer adhesive by irradiating it with ultraviolet light or the like.

The acryl type adhesive material which is used is desirably one which has no turbidity or tint, and which has high transparency, and it is desirable for its refractive index to be 1.45 to 1.55. It should be understood that, in this specification, the refractive index of the adhesive layer is the one which is measured based upon Method A as described in JIS-K-7142 (1996).

Furthermore, with the anisotropic light diffusion adhesive layer of the present invention, it is desirable to implement adjustment of the adhesive force so that the 180° peeling off strength falls within the range of 100 to 2000 g/25 mm, based upon JIS-Z-0237 (1980). With a 180° peeling off strength which is below 100 g/25 mm, the environmental resistance becomes insufficient, and, in particular, there is a fear that detachment will occur during high temperature and/or high humidity; while, on the other hand, with one which exceeds 2000 g/25 mm, it is difficult to rectify errors in the adhesion, and, even if it has been possible to rectify such an error, the situation is not desirable, because there is a danger that some adhesive material will remain upon the portion which has been peeled away.

(An Acicular Filler)

The acicular filler which is used for the present invention has a refractive index which is different from that of the adhesive material, and it is not particularly limited, provided that it is a filler of high aspect ratio which exhibits an acicular quality (i.e., which includes a material in fibrous form); but, if the anisotropic light diffusion adhesive layer of the present invention is to be used in a liquid crystal display device or in a backlight for a liquid crystal display device, it is desirable for the filler to be one which is colorless or white colored, in order to preserve the color of the transmitted light.

In concrete terms, an acicular or fibrous material such as one which is made from a metallic compound such as titanium oxide, zirconium oxide, a metallic oxide such as lead oxide or the like, boehmite, aluminum borate, calcium silicate, basic magnesium sulfate, calcium carbonate, potassium titanate, or the like, or glass or a composite resin or the like, is desirably employed.

As far as the size of the acicular filler is concerned, it is desirable for the long dimension to be from 2 to 5000 μm, and for the short dimension to be from 0.1 to 20 μm; and it is particularly desirable for the long dimension to be from 10 to 300 μm, and for the short dimension to be from 0.3 to 5 μm. If the long dimension is less than 2 μm or greater than 5000 μm, then it becomes difficult to disperse the acicular filler within the adhesive layer and to orient it properly; and this is not desirable, since there is a fear that it will not be possible for it to exhibit its anisotropic light diffusion function properly. On the other hand, with the short dimension being less than 0.1 μm, along with it being difficult to disperse and to orient the acicular filler properly, there is a fear that its light diffusion function may be deteriorated; while, with a short dimension which is greater than 20 μm, this is not desirable, since this will entail strong glareness of the diffused light.

(A Non-Acicular Filler)

The non-acicular filler which is used for the present invention is not particularly limited, provided that it is a filler whose refractive index is different from that of the adhesive material, and that it is one which is non-acicular; for example, a globular filler or a filler of indeterminate form may be cited. Desirably, due to the same reason as for the acicular filler, this non-acicular filler should be colorless or white colored. In concrete terms, as a globular filler, there may desirably be used minute particles of a resin such as acryl resin, polystyrene resin, a styrene—acryl copolymer resin, polyethylene resin, epoxy resin, or the like.

Furthermore, as a filler of indeterminate form, there may be cited an inorganic type white colored pigment such as silica, calcium carbide, aluminum hydroxide, magnesium hydroxide, clay, talk, titanium dioxide, or the like. It should be understood that, in the present invention, by a filler of indeterminate form is meant one which does not exhibit clear acicularity or globularity, and which, even though it has a fixed crystalline form, cannot be effectively oriented within the adhesive layer, so that, due to this, it is one which cannot contribute to diffusion anisotropy.

If this type of non-acicular filler is further included, by varying its ratio to the acicular filler, it is possible to cause any light diffusion property to be manifested, between the case when only acicular filler is included, and the case in which only non-acicular filler is included.

The particle diameter of the non-acicular filler (JIS B 9921) is normally in the range 0.1 to 20.0 μm, desirably 1.0 to 10.0 μm, and more desirably 0.5 to 10 μm. When the particle diameter is less than 0.1 μm, it may happen that the light diffusion property is deteriorated; while, when the particle diameter is greater than 20.0 μm, this is not desirable, since this will entail strong glareness of the diffused light.

Although, for the present invention, it is indispensable for the refractive indexes of the acicular filler and of the non-acicular filler to be different, in order to manifest a suitable light diffusion function, it is desirable for the refractive index difference to be greater than or equal to 0.01, and it is particularly desirable for it to be greater than or equal to 0.05. It should be understood that, in this specification, this refractive index of the filler is one which is measured based upon Method B described in JIS K-7142 (1996).

The amount of the acicular filler which is included in the anisotropic light diffusion adhesive layer of the present invention is not particularly limited, but is suitably designed according to the desired optical properties, the size and the proportional amount of the acicular filler, the difference between the refractive indexes of the adhesive material and the acicular filler, and the like; and it is desirable for it to be 0.1 to 50.0 mass percent, and it is particularly desirable for it be 5 to 45 mass percent. With an included amount of acicular filler which is less than 0.1 mass percent, there is a fear that the light diffusion performance will be insufficient; while, since if it exceeds 50.0 mass percent there is a fear that the adhesive force will be deteriorated and stripping away will occur, this is not desirable.

Furthermore, if a non-acicular filler is included, for the same reason as described above, it is desirable for the total included amount of the acicular filler and of the non-acicular filler to be 0.1 to 50.0 mass percent.

The thickness of the anisotropic light diffusion adhesive layer of the present invention is not particularly limited, but it is desirable for it to be 1 to 50 μm, and it is particularly desirable for it to be 10 to 30 μm. With a thickness of the anisotropic light diffusion adhesive layer which is less than 1 μm, there is a fear that it will not be possible to manifest a sufficient adhesive force and anisotropic light diffusion function; while, with one exceeding 50 μm, this is not desirable, since it is not possible to obtain further improvement of the optical properties, and the manufacturing efficiency also becomes bad.

(A Method of Manufacturing the Anisotropic Light Diffusion Adhesive Layer)

In the following, a method of manufacturing the anisotropic light diffusion adhesive layer of the present invention will be explained.

The anisotropic light diffusion adhesive layer of the present invention may be easily manufactured by, for example, manufacturing a filler-containing adhesive composite by dispersing an acicular filler and, according to requirements, a non-acicular filler, in an adhesive material, and, after this has been coated upon a base material such as a removable sheet or some type of optical element or the like, by eliminating the solvent therein by drying, by laminating a removable sheet or some type of optical element or the like upon it, and furthermore, according to requirements, by curing it for about 1 day to 2 weeks in an environment at room temperature, or at a temperature of 30° C. to 60° C., in order to harden or to stabilize the adhesive material component.

Generally, an adhesive material such as an acryl type adhesive material or the like is marketed in a form which includes a solvent such as acetic acid ethyl, acetone, methyl ethyl ketone, toluene or the like; but, for manufacturing a filler-containing adhesive composite, in order to enhance its aptitude for being coated, such as its wettability, its leveling property, its drying property, and the like, apart from the above described solvents, according to requirements, it would also be acceptable to add a solvent such as acetic acid butyl, methyl iso butyl ketone, cyclo hexanone, or the like.

Furthermore, in order to enhance the dispersivity of the acicular filler within the adhesive material, it is also acceptable to reform the surface of the filler by processing the surface of the filler in advance with a dispersivity enhancement substance such as an oily material, a surfactant material, a silane coupling material, or the like. It should be understood that, instead of applying such a dispersivity enhancement substance to the surface of the acicular filler, it would also be possible to combine it into the filler-containing adhesive composite. The dispersion of the acicular filler within the adhesive material may be performed by using a mixing and stirring device of various types, such as a disper, an agitor, a ball mill, an attriter, or the like, or a dispersion device or the like.

Furthermore, according to requirements, it is also possible to add a coloring dye, a fluorescent dye, a thickening material, a surfactant, a leveling material, or the like to the filler-containing adhesive composite.

It is desirable to de-foam the filler-containing adhesive composite which has been manufactured in advance, before coating it upon the base material. This coating of the filler-containing adhesive composite may be performed, for example, by using a coater such as a reverse coater, a dam coater, a comma coater, a die coater, a doctor bar coater, a glavier coater, a micro glavier coater, a roll coater, or the like.

It is possible to manufacture the anisotropic light diffusion adhesive layer of the present invention comparatively easily by dispersing the acicular filler so that it is oriented in a generally uniform direction, since, when coating on the, the acicular filler fibers are oriented so that almost all their long axes extend along the direction of coating, due to the shearing force upon the filler-containing adhesive composite. It should be understood that the degree of orientation of the acicular filler may be adjusted according to the size of the acicular filer, the viscosity of the filler-containing adhesive composite, the method of coating, the speed of coating, and the like. Furthermore, the thickness of the anisotropic light diffusion adhesive layer which is manufactured may be easily adjusted according to the coating thickness of the filler-containing adhesive composite, the amount of solvent in the filler-containing adhesive composite, and the like.

Since, according to the present invention, an acicular filler is employed which has a refractive index which is different from that of the adhesive material, and which has a structure in which it is dispersed in an orientation which is generally in a uniform direction, accordingly it is possible to provide an anisotropic light diffusion adhesive layer which is endowed with both an anisotropic light diffusion function and also an adhesive function.

As has been described above, the anisotropic light diffusion adhesive layer of the present invention is one which can be manufactured comparatively easily by producing a filler-containing adhesive composite, and by coating it on and drying it. Moreover, with the anisotropic light diffusion adhesive layer of the present invention, it is possible to adjust the anisotropy of the transmitted light according to the amount of orientation of the acicular filler and its size and the like, which is very suitable. Furthermore, with the anisotropic light diffusion adhesive layer of the present invention, it is possible easily to adjust its thickness, according to the coating thickness of the filler-containing adhesive composite, the amount of solvent within the filler-containing adhesive composite, and the like, which is very suitable.

The anisotropic light diffusion adhesive layer of the present invention may be suitably taken advantage of in various types of optical device, such as a liquid crystal display device, or the backlight for a liquid crystal display device, or the like.

(A Laminated Assembly)

When the anisotropic light diffusion adhesive layer of the present invention is utilized in various types of optical device such as a liquid crystal display device or a backlight for a liquid crystal display device or the like, it is possible to assemble it in the form of a laminated assembly.

As the concrete configuration of a laminated assembly which includes the anisotropic light diffusion adhesive layer of the present invention, there may be cited:
(1) one in which an anisotropic light diffusion adhesive layer of the present invention is formed upon a separator;
(2) one in which an anisotropic light diffusion adhesive layer is sandwiched between a pair of separators;
(3) one in which an anisotropic light diffusion layer according to the present invention and a separator are laminated in order upon an optical element which is selected from a light reflection element, a light diffusion element, a prism element, a light polarization element, a phase difference element, and a viewing angle magnification element;
(4) one in which an anisotropic light diffusion layer according to the present invention and a light reflection element are laminated in order upon a surface of the light guiding plate opposite from a light emission surface of the light guiding plate;
(5) one in which an anisotropic light diffusion adhesive layer according to the present invention is formed upon the light emission surface of a light guiding plate, and a light diffusion element and/or a prism element are provided upon the anisotropic light diffusion adhesive layer;
(6) one in which a light diffusion element, an anisotropic light diffusion adhesive layer according to the present invention, and a prism element are laminated together in order;
(7) one in which a prism element, an anisotropic light diffusion adhesive layer according to the present invention, and a light polarization element are laminated together in order;
(8) one in which a light reflection type polarization element, an anisotropic light diffusion adhesive layer according to the present invention, and a light absorption type polarization element are laminated together in order;
(9) one in which a phase difference element, an anisotropic light diffusion adhesive layer according to the present invention, and a light polarization element are laminated together in order; and the like.

It should be understood that, by “separator”, there is meant a release film or a release paper which has been provided with a release processing upon one surface, or upon both surfaces.

Furthermore, for the light polarization element, apart from a normal type of “light absorption type polarization element” which absorbs all light other than only light of a specified polarization which passes through, it is supposed that there is included a “light reflection type polarization element” which reflects all light other than only light of a specified polarization which passes through. For the light reflection type polarization element, for example, there are marketed “DBEF” of the 3M Company, which is a structure in which two types of polyester resin (PEN and PEN copolymer), which have different refractive indexes in the direction of extension when they have been stretched out, are laminated alternately in several hundreds of layers by an extrusion forming technique and are stretched out, or “Nippox (a trademark)”, made by Nitto Denko Company or “Transmax (TRANSMAX, a trademark)” made by Merck Company, which are structures which are made by laminating together a cholesteric liquid crystal polymer layer and a ¼ wavelength plate, and with which light which is incident from the side of the cholesteric liquid crystal polymer layer is separated into two circularly polarized light beams of mutually opposite orientation, of which one passes through while the other is reflected, with the circularly polarized light which has passed through the cholesteric liquid crystal polymer layer being converted into linearly polarized light by ¼ wavelength reflection, and the like.

With the laminated assembly (1), if peel away processing on both surfaces is implemented by using separators, it is also possible, after having coated the filler-containing adhesive composite upon the separators, and having dried it, to roll it up just as it is, which is desirable.

Furthermore, as a method of manufacturing the laminated assemblies (3) through (9), there may be cited a method of forming the anisotropic light diffusion adhesive layer by directly coating an filler-containing adhesive composite upon the optical element, and laminating the optical element or the separator upon this; or a method of taking advantage of the laminated assembly (1) or (2), and laminating the optical element upon this; or, furthermore, a method of, after having temporarily produced a laminated assembly of the separator, the anisotropic light diffusion adhesive layer, and an optical element, laminating the other optical element by peeling away the separator; or the like.

(An Illumination Device)

The illumination device of the present invention is characterized by comprising an anisotropic light diffusion adhesive layer of the present invention as described above, and, in terms of its concrete specification, it is an illumination device which has as indispensable structural members a light source, a light guiding plate, and a light reflection element, while it has, as optional structural members, a light diffusion element, a prism element, a light polarization element, a phase difference element, and a viewing angle magnification element; and an anisotropic light diffusion adhesive layer according to the present invention is sandwiched between a pair of optical elements which are selected from a light guiding plate, a light reflection element, a light diffusion element, a prism element, a light polarization element, a phase difference element, and a viewing angle magnification element. The pair of optical elements may be the same type of optical element, or may be different types of optical device.

By building an illumination device using the anisotropic light diffusion adhesive layer of the present invention, it is possible to anticipate increase of the viewing angle, improvement of the evenness of the illumination, and elimination of bright lines and/or dark lines. Furthermore, it is possible to anticipate enhancement of the thinness, since it is possible to build the adhesive layer and the anisotropic light diffusion layer as a single layer, thus reducing the number of component members, which is very desirable. The illumination device of the present invention may be appropriately utilized as a backlight for a liquid crystal device or the like.

### EMBODIMENTS

Next, embodiments of the present invention and comparison examples will be explained.

### Embodiment 1

7 mass portions of aluminum borate whiskers (long dimension 10 to 30 μm, short dimensions 0.5 to 1.0 μm, refractive index 1.60) were added as an acicular filler to 150 mass portions of an acryl type adhesive material (overall solid content 30%, solvent: ethyl acetate, methyl ethyl ketone, refractive index of the solid content 1.47), and furthermore 120 mass portions of a dissolved mixture of toluene and ethyl acetate were added, and the mixture was stirred using an agitator for 30 minutes, so that the acicular filler was dispersed. 0.7 mass portions of an isocyanate type hardener was added to and properly mixed into this liquid dispersion, so as to produce a filler-containing adhesive composite.

This composite was coated upon a transparent PET film of 75 μm thickness by using an applicator, and was dried for 3 minutes at 100° C., so as to manufacture an anisotropic light diffusion adhesive layer. A release type PET film (a separator) of 38 μm thickness was laminated upon this anisotropic light diffusion adhesive layer, so that the anisotropic light diffusion adhesive layer was sandwiched between the pair of PET films, whereby an anisotropic light diffusion adhesive laminated assembly was obtained. The thickness of the anisotropic light diffusion adhesive layer which was manufactured was 19 μm. Furthermore, by observation using an optical microscope, it was confirmed that the acicular filler fibers were oriented so their long axes lay almost along the direction of coating.

The laminated assembly which was obtained was disposed parallel to and at a distance of 10 cm from a piece of white paper, and, when a straight light beam was caused to be perpendicularly incident from above onto the laminated assembly, an optical image of an elliptical shape, stretched in the direction which was orthogonal to the lengthwise axis direction of the acicular filler fibers, was projected upon the paper (refer to FIGS. 2A and 2B).

### Embodiment 2

A laminated assembly was obtained by the same procedure as in Embodiment 1, except that, instead of adding 7 mass portions of aluminum borate whiskers as an acicular filler, 6 mass portions (long dimension 10 to 30 μm, short dimensions 0.5 to 1.0 μm, refractive index 1.60) of aluminum borate whiskers were added as an acicular filler, and 5 mass portions of minute particles made from a silicone resin (average particle diameter 4.5 μm, refractive index 1.43) were added as a globular filler.

The thickness of the anisotropic light diffusion adhesive layer which was produced was 19 μm. Furthermore, when observed using an optical microscope, it was confirmed that the long axis of the acicular filler extended almost along the direction in which it was coated.

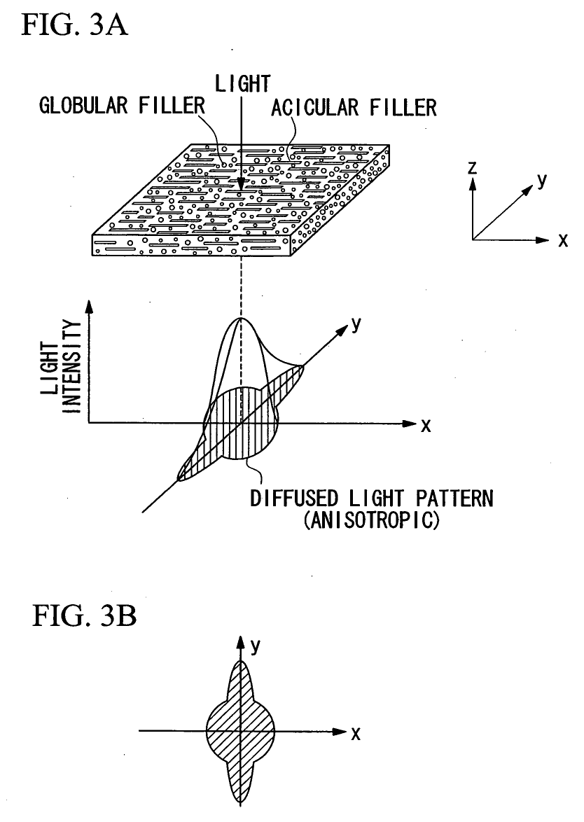

The laminate assembly which was obtained was disposed parallel to and at a distance of 10 cm from a sheet of white paper, and, when a straight light beam was directed from above upon the laminated assembly so as to be perpendicularly incident upon it, its central portion was widened out in an indistinct circle, while, in the direction from its central portion which was orthogonal to the lengthwise axis direction of the acicular filler, an optical image which was stretched out so as to be long and thin was projected upon the paper (refer to FIGS. 3A and 3B).

### Embodiment 3

Two laminated assemblies according to the above described Embodiment 1 were prepared, and the separator of each of them was removed. These two laminated assemblies were arranged so that the directions of orientation of their acicular fillers were mutually orthogonal, and their individual adhesive surfaces were then joined together, so as to produce an anisotropic light diffusion adhesive laminated assembly.

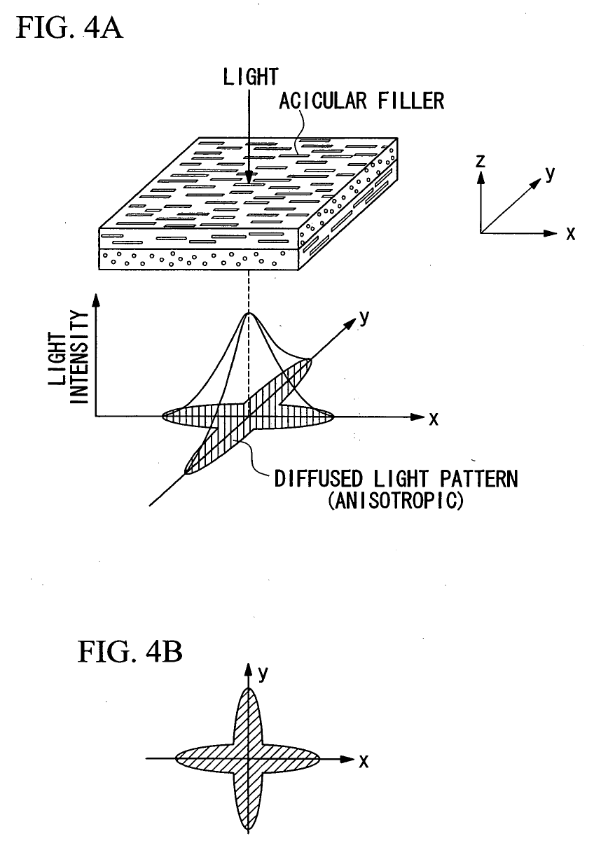

When its optical image was observed by the same method as in Embodiment 1, a cross shaped optical image was projected upon the paper (refer to FIGS. 4A and 4B).

### COMPARATIVE EXAMPLE 1

A laminated assembly was obtained by the same procedure as in Embodiment 1, except that, instead of an acicular filler, a globular filler—in more concrete terms, globular minute particles made from polystyrene of diameter 5 μm (refractive index 1.59)—was used.

When the projected image was observed in the same was as with the Embodiments, it was ascertained that it was circular (refer to FIGS. 5A and 5B). This was because the light was diffused isotropically.

### INDUSTRIAL APPLICABILITY

As has been explained above, according to the present invention, it is possible to provide an anisotropic light diffusion adhesive layer which is endowed with both an anisotropic light diffusion function and an adhesive function, and a laminated assembly and an illumination device which employ the same; and furthermore it is possible to provide an anisotropic light diffusion adhesive laminated assembly which is endowed with both an anisotropic light diffusion function and an adhesive function, and a multi layer sheet and an optical laminated assembly which employ the same.

The anisotropic light diffusion adhesive layer according to the present invention can be manufactured comparatively easily, and moreover it is one for which the degree of anisotropy of the transmitted light and the thickness can also easily be adjusted. Furthermore, with the anisotropic light diffusion adhesive laminated assembly according to the present invention, various optical properties can be obtained according to the type of filler which is added and according to its direction of orientation, and moreover it can be manufactured comparatively easily, and it is one for which the degree of anisotropy of the transmitted light and the thickness can also easily be adjusted. By using the anisotropic light diffusion adhesive layer or the anisotropic light diffusion adhesive laminated assembly according to the present invention in an illumination device such as a backlight for a liquid crystal display device or the like, it is possible to implement enlargement of the viewing angle, more even illumination intensity, elimination of bright lines and dark lines, reduction of the number of elements, and enhancement of thinness.

1. An anisotropic light diffusion adhesive layer comprising:
an adhesive material; and
an acicular filler whose refractive index is different from that of the adhesive material,
wherein the acicular filler is dispersed as oriented substantially in the same direction.

2. An anisotropic light diffusion adhesive layer according to claim 1, wherein the acicular filler is colorless or white colored.

3. An anisotropic light diffusion adhesive layer according to claim 1, further comprising a non-acicular filler.

4. An anisotropic light diffusion adhesive layer according to claim 3, wherein the non-acicular filler is colorless or white colored.

5. A laminated assembly comprising an anisotropic light diffusion adhesive layer according to claim 1.

6. A laminated assembly according to claim 5, further comprising a separator, wherein the anisotropic light diffusion adhesive layer is formed above the separator.

7. A laminated assembly according to claim 5, further comprising a pair of separators, wherein the anisotropic light diffusion adhesive layer is sandwiched between the pair of separators.

8. A laminated assembly according to claim 5, further comprising an optical element selected from a light reflection element, a light diffusion element, a prism element, a light polarization element, a phase difference element, and a viewing angle magnification element, and a separator; wherein the anisotropic light diffusion adhesive layer and the separator are laminated in order upon the optical element.

9. A laminated assembly according to claim 5, further comprising a light guiding plate and a light reflection element, wherein the anisotropic light diffusion adhesive layer and the light reflection element are laminated in order upon a surface of the light guiding plate opposite from a light emission surface of the light guiding plate.

10. A laminated assembly according to claim 5, further comprising a light guiding plate and at least one of a light diffusion element and a prism element, wherein the anisotropic light diffusion adhesive layer is formed upon a light emission surface of the light guiding plate, and at least one of the light diffusion element and the prism element is provided upon the anisotropic light diffusion adhesive layer.

11. A laminated assembly according to claim 5, further comprising a light diffusion element and a prism element, wherein the light diffusion element, the anisotropic light diffusion adhesive layer, and the prism element are laminated together in order.

12. A laminated assembly according to claim 5, further comprising a prism element and a light polarization element, wherein the prism element, the anisotropic light diffusion adhesive layer, and the light polarization element are laminated together in order.

13. A laminated assembly according to claim 5, further comprising a light reflection type polarization element and a light absorption type polarization element, wherein the light reflection type polarization element, the anisotropic light diffusion adhesive layer, and the light absorption type polarization element are laminated together in order.

14. A laminated assembly according to claim 5, further comprising a phase difference element and a light polarization element, wherein the phase difference element, the anisotropic light diffusion adhesive layer, and the light polarization element are laminated together in order.

15. An illumination device comprising an anisotropic light diffusion adhesive layer according to claim 1.

16. An illumination device according to claim 15, further comprising a light source, a light guiding plate, and a light reflection element, wherein the anisotropic light diffusion adhesive layer is sandwiched between a pair of optical elements selected from the light guiding plate and the light reflection element.

17. An illumination device according to claim 15, comprising a light source, a light guiding plate, and a light reflection element, and further comprising at least one optical element selected from a light diffusion element, a prism element, a light polarization element, a phase difference element, and a viewing angle magnification element, wherein the anisotropic light diffusion adhesive layer is sandwiched between a pair of optical elements selected from the light guiding plate, the light reflection element, the light diffusion element, the prism element, the light polarization element, the phase difference element, and the viewing angle magnification element.

18. An anisotropic light diffusion adhesive laminated assembly comprising two or more adhesive layers which comprise an adhesive material, wherein at least one of the adhesive layers comprises an acicular filler whose refractive index is different from that of the adhesive material, and the acicular filler is dispersed as oriented substantially in the same direction.

19. An anisotropic light diffusion adhesive laminated assembly according to claim 18, comprising at least two adhesive layers each of which comprises an acicular filler, wherein the acicular filler included in each of the adhesive layers is oriented in a different direction from the acicular fillers included in the other adhesive layers.

20. An anisotropic light diffusion adhesive laminated assembly according to claim 18, wherein at least one adhesive layer comprises a non-acicular filler.

21. An anisotropic light diffusion adhesive laminated assembly according to claim 18, wherein at least one adhesive layer comprises a non-oriented acicular filler.

22. An anisotropic light diffusion adhesive laminated assembly according to claim 18, comprising a transparent adhesive layer which comprises neither an acicular filler nor a non-acicular filler.

23. An anisotropic light diffusion adhesive laminated assembly according to claim 18, wherein the acicular filler is colorless or white colored.

24. An anisotropic light diffusion adhesive laminated assembly according to claim 20, wherein the non-acicular filler is colorless or white colored.

25. A multi layer sheet comprising:
an anisotropic light diffusion adhesive laminated assembly according to claim 18; and
a transparent base material which has two surfaces,
wherein the anisotropic light diffusion adhesive laminated assembly is provided upon at least one of the surfaces of the transparent base material.

26. A multi layer sheet comprising:
an anisotropic light diffusion adhesive laminated assembly according to claim 18; and
a separator,
wherein the anisotropic light diffusion adhesive laminated assembly is provided upon the separator.

27. A multi layer sheet comprising:
an anisotropic light diffusion adhesive laminated assembly according to claim 18; and
a pair of separators,
wherein the anisotropic light diffusion adhesive laminated assembly is sandwiched between the pair of separators.

28. An optical laminated assembly comprising:
an anisotropic light diffusion adhesive laminated assembly according to claim 18;
a separator; and
an optical element selected from a light reflection element, a light diffusion element, a prism element, a light polarization element, a phase difference element, and a viewing angle magnification element,
wherein the anisotropic light diffusion adhesive laminated assembly and the separator are laminated in order upon the optical element.

29. An optical laminated assembly comprising:
an anisotropic light diffusion adhesive laminated assembly according to claim 18;
a light guiding plate; and
a light reflection element,
wherein the anisotropic light diffusion adhesive laminated assembly and the light reflection element are laminated in order upon a surface of the light guiding plate opposite from a light emission surface of the light guiding plate.

30. An optical laminated assembly comprising:
an anisotropic light diffusion adhesive laminated assembly according to claim 18;
a light guiding plate; and
at least one of a light diffusion element and a prism element,
wherein the anisotropic light diffusion adhesive laminated assembly is formed upon a light emission surface of the light guiding plate, while at least one of the light diffusion element and the prism element is provided upon the anisotropic light diffusion adhesive laminated assembly.

31. An optical laminated assembly comprising:
an anisotropic light diffusion adhesive laminated assembly according to claim 18;
a light diffusion element; and
a prism element,
wherein the light diffusion element, the anisotropic light diffusion adhesive laminated assembly, and the prism element are laminated together in order.

32. An optical laminated assembly comprising:
an anisotropic light diffusion adhesive laminated assembly according to claim 18;
a prism element; and
a light polarization element,
wherein the prism element, the anisotropic light diffusion adhesive laminated assembly, and the light polarization element are laminated together in order.

33. An optical laminated assembly comprising:
an anisotropic light diffusion adhesive laminated assembly according to claim 18;
a light reflection type polarization element, and
a light absorption type polarization element,
wherein the light reflection type polarization element, the anisotropic light diffusion adhesive laminated assembly, and the light absorption type polarization element are laminated together in order.

34. An optical laminated assembly comprising:
an anisotropic light diffusion adhesive laminated assembly according to claim 18;
a phase difference element, and
a light polarization element,
wherein the phase difference element, the anisotropic light diffusion adhesive laminated assembly, and the light polarization element are laminated together in order.

35. An illumination device comprising an anisotropic light diffusion adhesive laminated assembly according to claim 18.

36. An illumination device comprising:
an anisotropic light diffusion adhesive laminated assembly according to claim 18;
a light source;
a light guiding plate; and
a light reflection element,
wherein the anisotropic light diffusion adhesive layer is sandwiched between a pair of optical elements selected from the light guiding plate and the light reflection element.

37. An illumination device, comprising:
an anisotropic light diffusion adhesive laminated assembly according to claim 18;
a light source, a light guiding plate;
a light reflection element; and
at least one optical element which is selected from a light diffusion element, a prism element, a light polarization element, a phase difference element, and a viewing angle magnification element,
wherein the anisotropic light diffusion adhesive layer is sandwiched between a pair of optical elements selected from the light guiding plate, the light reflection element, the light diffusion element, the prism element, the light polarization element, the phase difference element, and the viewing angle magnification element.
